(19) United States
(12) Patent Application Publication
(10) Pub. No.: US 2025/0279274 A1
(43) Pub. Date: Sep. 4, 2025

(54) VAPOR DRYER WITH INTEGRATED PARTICLE MONITORING

(71) Applicant: Applied Materials, Inc., Santa Clara, CA (US)

(72) Inventors: Michael J. COUGHLIN, Livermore, CA (US); Garrett Ho Yee SIN, San Jose, CA (US)

(21) Appl. No.: 18/593,206

(22) Filed: Mar. 1, 2024

(51) Int. Cl. H01L 21/02; H01L 21/67

(52) U.S. Cl. CPC H01L 21/02074; H01L 21/67253

(57) ABSTRACT

An apparatus and method for drying substrates is proved, comprising a containment tank having a rinsing liquid region and a headspace a particle detector, comprising an inlet line extending into the rinsing liquid region of the containment tank; a detection unit configured to receive a flow of liquid from the inlet line therethrough; an outlet line extending from the detection unit and into the containment tank; and a pump connected to one of the inlet line, outlet line or detection unit and configured to cause fluid to be drawn from the containment tank through the inlet line and returned to the containment tank through the outlet line a controller configured to receive information from the detection unit.

### BACKGROUND

### Field

The present disclosure relates to the post-polishing cleaning and drying of substrates

### Description of the Related Art

An integrated circuit is typically formed, in part, by the sequential deposition of conductive, semiconductive or insulative layers on a semiconductor substrate, for example a silicon wafer, and by the subsequent processing of the layers.

One fabrication step involves depositing a filler layer over a non-planar surface, and planarizing the filler layer until projecting portions of the upper or outer surface of the non-planar surface are exposed. For example, a conductive filler layer can be deposited on a patterned insulative layer to fill the trenches or holes in the insulative layer. The filler layer is then polished until the upper or outer surface of the insulative layer, i.e., the area of the underlying layer between the holes or trenches, is exposed. This yields a patterned insulative layer having the conductive filler layer embedded into the trenches or holes, which is exposed at the upper or outer surfaces thereof.

Chemical mechanical polishing (CMP) is one accepted method of planarization. This planarization method typically requires that the substrate be mounted on a carrier head. The exposed surface (upper or outer surface) of the substrate is placed against a rotating polishing pad. The carrier head provides a controllable load on the substrate to push the surface thereof to be planarized against the polishing pad. A polishing liquid, such as slurry with abrasive particles therein, is supplied to the surface of the polishing pad. For example, cerium oxide can be used as an abrasive particle in the polishing of copper filler layers in CMP. In some cases, the particles are supplied from the pad, which is known as a fixed abrasive pad.

The slurry of abrasive particles can include cerium oxide particulates and organic additives, and can include other carbon-based residues from the polishing process. These must be removed before other processes can be performed on the substrate, such as the deposition of additional film layers formed over the polished surface of the substrate. To remove these particulates, the substrates can be subjected to a cleaning process that can include the use of harsh oxidizing solvents. For example, a mixture of sulfuric acid and hydrogen peroxide (SPM) can be used in the removal of cerium oxide particulates from the surfaces of a substrate after polishing. SPM cleaning can be performed in a parallel separated mode in which each substrate is placed in a bath in a separate container. The substrates are then subjected to wet scrubbing of the surfaces thereof with a physical contact module such as a brush or roller, followed by immersion in an ultrasonically agitated liquid bath. A final drying step is then performed in a dryer after the cleaning. The desire is for the substrate to exhibit a particle free, dry surface after the drying step.

The objective of drying the substrate is to ensure a clean, dry substrate comes out of the post polishing cleaning and drying apparatus. However, it is known that particulates can be present on the substrate as it enters the dryer. These particulates may, for example, be slurry particulates or particles of the substrate cleaning apparatus itself, such as particulates generated by the breaking down of the rollers and brushes used to scrub the substrate after the polishing thereof. These particulates can become free of, i.e., detach from, the substrate while it is being dried in the dryer, and accumulate in the liquid used in the drying process. The probability of one or more of the particles in the liquid in the dryer reattaching to a substrate increases as the concentration of the particles in the liquid in the dryer increases. The presence of particles on the substrate after cleaning can result in the manufacture of one or more defective semiconductor die on the substrate.

### SUMMARY

In one aspect, an apparatus for drying substrates, comprises a containment tank having a liquid receiving region and a vapor receiving region a particle detector, comprising an inlet line extending into the liquid receiving region of the containment tank; a detection unit configured to receive a flow of liquid from the inlet line therethrough; an outlet line extending from the detection unit and into the containment tank; and a pump connected to one of the inlet line, outlet line or detection unit and configured to cause fluid to be drawn from the containment tank through the inlet line and returned to the containment tank through the outlet line, and a controller configured to receive information from the detection unit.

In another aspect, a polishing, cleaning and drying apparatus, comprises at least one physical contact module, a containment tank having a liquid receiving region and a vapor receiving region; a robot arm extendible into the physical contact module and into the containment tank; a particle detector, comprising an inlet line extending into the liquid receiving region of the containment tank; a detection unit configured to receive a flow of liquid from the inlet line therethrough; an outlet line extending from the detection unit and into the containment tank; and a pump connected to one of the inlet line, outlet line or detection unit and configured to cause fluid to be drawn from the containment tank through the inlet line and returned to the containment tank through the outlet line.

In another aspect, a method of drying a substrate comprises providing a containment tank having a liquid region with a cleaning liquid therein and a vapor receiving region extending over the liquid region; sequentially submersing a plurality of substrates into the cleaning liquid in the liquid region; providing a particle detector, comprising an inlet line extending into the cleaning liquid receiving region of the containment tank; a detection unit configured to receive a flow of liquid from the inlet line therethrough; an outlet line extending from the detection unit and into the containment tank; passing the cleaning liquid through the inlet line and through the detection unit; and determining at least one of the size and shape of any particle detected by the detection unit.

The details of one or more implementations are set forth in the accompanying drawings and the description below. Other aspects, features and advantages will be apparent from the description and drawings, and from the claims.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic top view of a chemical mechanical polishing system.

FIG. 2A-C are schematic diagrams of a vapor dryer with a liquid particle counter attached thereto.

FIG. 3 is a schematic diagram of the liquid particle counter.

FIG. 4 is a schematic view of a robotic end effector grasping a substrate.

Like reference symbols in the various drawings indicate like elements.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

An embodiment disclosed herein is a vapor dryer configured to dry substrates that have been cleaned in a post-chemical mechanical polishing cleaner. The vapor dryer includes a liquid into which the substrates are submerged and are dried while being lifted out of the liquid during the vapor process. A fluid circuit is configured to pull the liquid from the vapor dryer and determine the presence of particles, the types of particles detected or both. Thus a determination can be made that the particulate of the slurry have not been removed by cleaning, particulates have been generated and become attached to the substrates during the cleaning process or both.

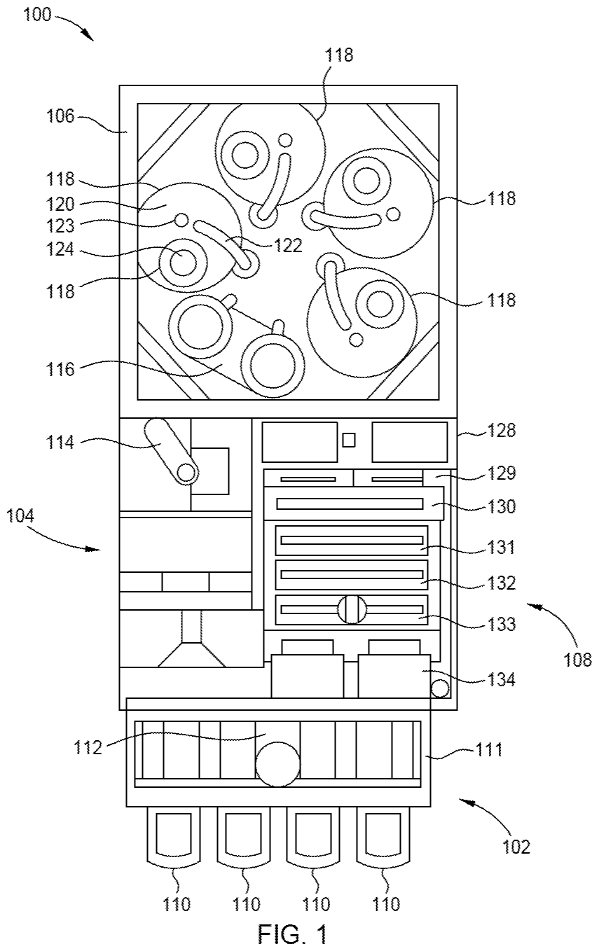

FIG. 1 illustrates an interior plan view of a chemical mechanical polishing (CMP) system 100. The system 100 generally includes a factory interface module 102, input module 104, a polisher module 106, and a cleaning module 108. The four major components are generally disposed and interconnected to provide the CMP system 100.

The factory interface 102 includes a support to hold plurality of substrate cassettes 110, a housing 111 that encloses a chamber, and one or more interface robots 112 within the housing 111. The factory interface robot 112 generally provides the range of motion required to transfer substrates between the cassettes 110 and the input module 104 and between the cleaning module 108 and the cassettes 110. Substrates to be processed in the chemical mechanical polishing system are generally transferred from the cassettes 110, through the housing 111 and into the input module 104 by the interface robot 112. A transfer robot is provided in the input module 104. The input module 104 generally facilitates transfer of the substrate between the interface robot 112 and the transfer robot 114. The transfer robot 114 transfers the substrate between the input module 104 and the polisher module 106.

The polisher module 106 generally comprises a transfer station 116, and one or more polishing stations 118. The transfer station 116 is disposed within the polishing module 106 and is configured to accept the substrate from the transfer robot 114. The transfer station 116 transfers the substrate to a carrier head 124 of a polishing station 118 that retains the substrate during polishing.

The polishing stations 118 includes a rotatable disk-shaped platen having a polishing pad-receiving surface, on which a polishing pad 120 is situated. The platen is operable to rotate about an axis generally perpendicular to the pad-receiving surface thereof. The polishing pad 120 can be a two-layer polishing pad with an outer polishing layer and a softer backing layer. The polishing stations 118 further includes a dispensing arm 122, to dispense a polishing liquid, e.g., an abrasive slurry, onto the polishing pad 120. In the abrasive slurry, the abrasive particles can be silicon oxide, but for some polishing processes use cerium oxide abrasive particles. The polishing station 118 can also include a conditioner head 123, which is actuated into selective contact with the exposed surface of the polishing pad to abrade the surface and maintain the polishing pad 120 at a consistent surface roughness.

The polishing stations 118 include at least one carrier head 124. The carrier head 124 is operable to hold a substrate 10 against the polishing pad 110 during a polishing operation. Following a polishing operation performed on a substrate, the carrier head 124 will transfer the substrate back to the transfer station 116.

The transfer robot 114 then removes the substrate from the polishing module 106 through an opening connecting the polishing module 106 with the remainder of the CMP system 100. The transfer robot 114 removes the substrate from the polishing module 106 with the polished surface thereof in a horizontal orientation, and reorients the substrate to position the polished surface in a vertical orientation for placement into the cleaning module 108.

The cleaning module 108 generally includes one or more cleaning devices that can operate independently or in concert. For example, the cleaning module 108 can include, from the top to the bottom of the page of in FIG. 1, an SPM module 128 (described further below), an input module 129, a physical contact module configured as one or more brush or buffing pad cleaners 131, 132, a megasonic cleaner 133, and a drying module 134. Other possible cleaning devices include chemical spin cleaners and jet spray cleaners. A transport system, e.g., an overhead conveyor 130 that supports robot arms, can walk or run the substrates from cleaning module device to cleaning module device, as well as insert them into, and remove them from, the cleaning module devices. Briefly, the one or more brush or buffing pad cleaners 131, 132 are devices in which a substrate can be placed and the surfaces of the substrate are contacted with rotating brushes or spinning buffing pads to remove any remaining particulates. The substrate is then transferred to the megasonic cleaner 133 in which high frequency vibrations (at one or more frequencies) are provided by a transducer to input energy into the cleaning liquid in the megasonic cleaner 133 to produce controlled cavitation in the cleaning liquid to remove particles and by-products of polishing from the substrate. Alternatively, the megasonic cleaner can be positioned before the brush or buffing pad cleaners 131, 132. A final rinse can be performed in a rinsing module before transferring the substrate to a drying module 134.

Although FIG. 1 illustrates the SPM module 128 as the first cleaning device in the sequence, this is not necessary for actual physical position or order of cleaning operations (although having the cleaning devices in same physical order as the order of operations will be more efficient for throughput). For example, the substrate could be processed by a brush or buffing pad cleaner (e.g., a buff pad), then by the SPM module, then by another brush or buffing pad cleaner (e.g., a rotating brush), and then by a jet spray cleaner.

As described above, the CMP system 100 transfers the substrates from the polishing module 106 into the cleaning module 108. Debris from the polishing process, e.g., abrasive particles or organic materials or other by-products of the polishing pad or slurry, can be stuck to the substrates. Some of these materials, e.g., cerium oxide particulates, and organic additives from the polishing module 106, are difficult to remove with the cleaners 131, 132, 133 listed above. Therefore, the substrates are moved to an in-line sulfuric peroxide mixture (SPM) module 128 within the cleaning module 108. The SPM module shown in FIG. 1 is a module that allows for the in-line SPM cleaning of a number of substrates concurrently. The SPM module 128 includes two containers, a cleaning container 124 and a rinse container 126. Here, where the SPM module is used, a separate robot dedicated to the loading of substrates thereinto and therefrom may be employed. Upon receiving a signal from a system controller, e.g., when the substrate 10a is grasped by a robot arm for the SPM module and inserted into the SPM module, and from the SPM module to a dedicated rinse station for rinsing the SPM chemistry from the substrate.

After the initial cleaning of a substrate in the SPM module, a robot arm of an overhead conveyor 130, the robot arm having an end effector 200 thereon, grasps the substrate 10a in a vertical orientation and moves it from the rinse station 128 to the input module 129. From the input module 129, the substrate is moved in the vertical orientation by the robot arm of the overhead conveyor 130 and then inserted downwardly into to one of the brush or buffing pad cleaners 131, 132. Alternatively, a robot arm of the overhead conveyor can move the substrate from the output station 182, through the input module 129, and thence into one of the brush or buffing pad cleaners 131, 132. After the brushing or buffing of the surface of the substrate, it is lifted by a robot arm of the overhead conveyor 130 from the brush or buffing pad cleaners 131, 132 and into moved over, and then lowered into, the megasonic cleaner 133 to remove particles, organics and other remaining residues of the polishing process therefrom. The substrate is then lifted out of the megasonic cleaner 133 by a robot arm of the overhead conveyor 130 into then moved over, and lowered into, the drying module 134. In the drying module 134, the substrate is submerged, in a vertical orientation, into a liquid, and then pulled (i.e. removed) from the liquid while a drying vapor is directed to the location where the substrate contacts the upper surface of a drying liquid.

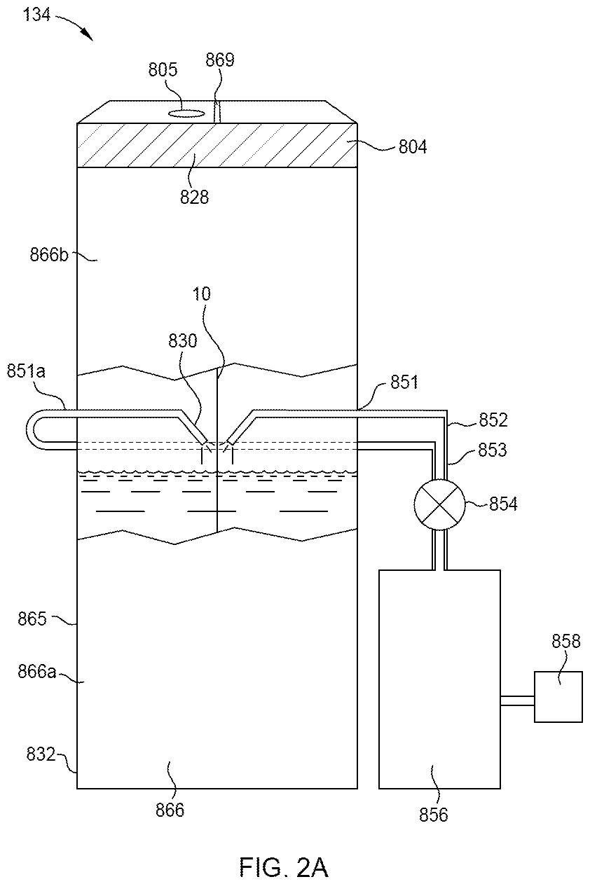

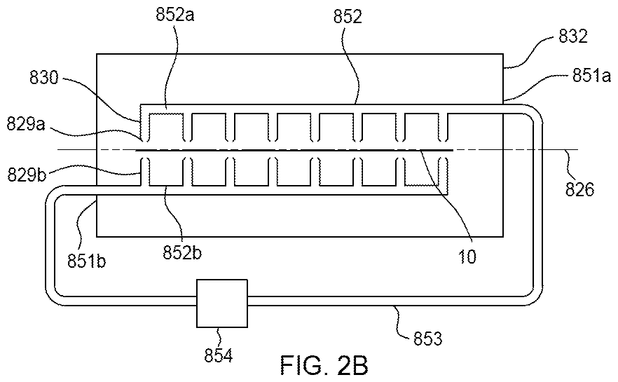

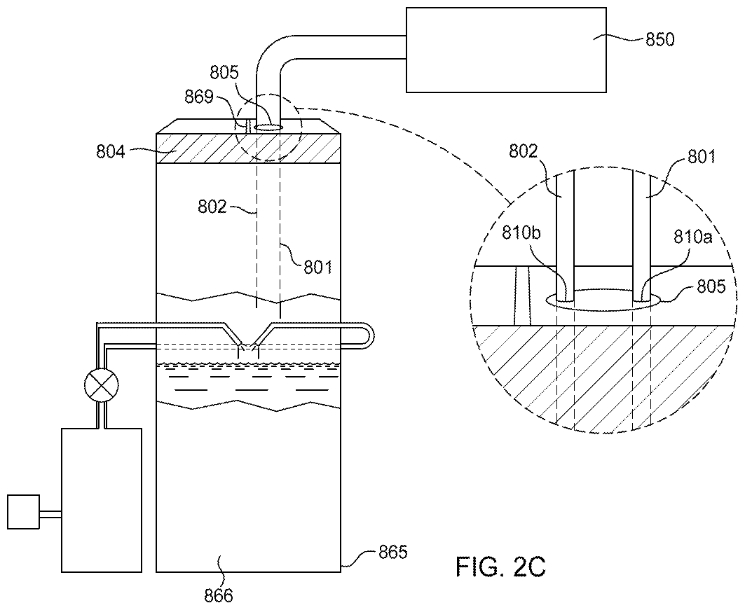

Referring now to FIGS. 2a to 2c, the drying module 134 is shown schematically to illustrate the basic functionality thereof, and generally includes a containment tank 865 configured to hold a rinsing liquid, for example, deionized water, and a source of drying vapor, for example a mixture of isopropyl alcohol and nitrogen. In FIG. 2a, the tank is shown in section from the side thereof. In FIG. 2b the tank is shown in plan view, and in FIG. 2c the tank is shown connected to a particle detection system. To dry a substrate after the cleaning thereof, the containment tank 865 is filled with a rinsing liquid 866a to a level at which the substrate 10a, in a vertical orientation, can be fully submerged in the rinsing liquid, while there is sufficient headspace 866b above the rinsing liquid region 866a for a substrate, in the vertical orientation, to be pulled up and out of the rinsing liquid 866a but still be within the confines of the tank 865. To supply the drying vapor, the containment tank 865 contains a port or a plurality of ports 851a, 851b, extending through the sidewall thereof at a location above the liquid, through which a plurality of nozzle bars 852 located within the headspace 866b are connected to the source of vapor. As seen in the top down view of FIG. 2b, the nozzle bar or bars 852 terminate inwardly of the containment tank 865 and include a plurality of nozzles 830 spaced along the length thereof within the headspace. Each nozzle bar 852 extends horizontally over the upper surface of the rinsing liquid 866a, and a plurality of nozzles 830, for example, two, four, six or eight nozzles extend from the outer surface thereof. The nozzles 830 may protrude from their respective nozzle bars 852 at an angle to a sidewall 832 of the containment tank 865 such that they extend downwardly and horizontally. Openings 829 are formed at the distal ends on the nozzles 830 opposite to the nozzle bar 852. The openings 829 are directed toward a center plane 826 of the containment tank 865 along which the substrate to be dried is lowered into the drying liquid 866 and pulled from the drying liquid 866. In the two nozzle bars 852a and 852b shown, a first set of openings 829a face the intersection of the center plane 826 of the containment tank 865 with the upper surface of the liquid and a second set of openings 829b also face the intersection of the center plane 826 of the containment tank 865 with the upper surface of the liquid, opposite to and facing the first set of openings 829a across the center plane 826 of the containment tank 865. Thus, gas or vapor released through the openings 829a and 829b is directed toward the intersection of the center plane 826 with the upper surface of the liquid. A substrate 10 passing along the center plane 826 will be impinged by the vapor or gas from the opening 829a and 829b generally equally on both sides thereof at the location where the opposed sides of the substrate are being lifted out of the drying liquid 866.

The distal end of the nozzle bar or bars 852 protrude from the ports 851a, 851b away from an outer side wall 832 of the containment tank 865. The nozzle bar or bars 852 are connected at a distal end thereof, external to the containment tank, to a first valve line 853. The first valve line 853 connects the nozzle bars 852 to a valve 854 at the outlet side thereof. A second valve line 855 is connected to the valve at the inlet side thereof. The second valve 855 line leads to and is in fluid communication with an opening in a vapor source, such as a bubbler 856. The bubbler 856 is a secondary containment tank located external to the containment tank 865. The bubbler 856 is configured to hold liquid isopropyl alcohol (IPA) and a secondary gas line 857 extends into the liquid IPA and is connected to a nitrogen source 858. The nitrogen source 858 provides nitrogen to the bubbler 856 through the gas line 857 at a quantity sufficient to supply IPA and Nitrogen to the containment tank 865 for a Marangoni drying process of the surface of the substrate as it is pulled out of the frying liquid. For example, the IPA may be carried on a small bubble of nitrogen, which is coated with IPA as it passes through the IPA in the bubbler 856. Thus, IPA and nitrogen are supplied from the bubbler 856 and enter into the containment tank 856 through the nozzle openings 829.

Referring to FIG. 2c, the containment tank 865 comprises an upper opening for placement of a substrate in the vertical orientation into the containment tank 865. The opening may be configured as a slit having a length greater that the diameter of the substrates to be dried. The vapor dryer tank cover 861 both covers and surrounds the upper end of the containment tank 865, but leaves opening 869 through which a substrate 10 may be disposed. The vapor dryer tank cover 861 further comprises a port 805, the port 805 having at least a first opening and a second opening 810a, 810b respectively.

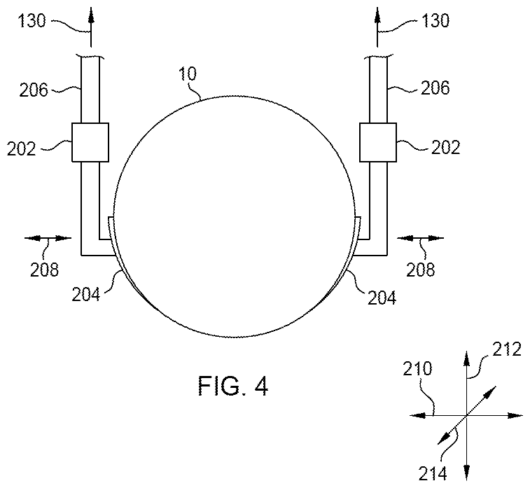

As shown in FIG. 4, an example of an end effector 200 useful for lowering the substrate 10 into the drying liquid 866a, and then lifting it therefrom and into the headspace 866b as the IPA dries. Nitrogen vapor is directed at the meniscus of the drying liquid 866 to substrate side surfaces is shown. Here, the end effector 200 is supported from above by the overhead conveyor 130, which moves the end effector 200, and lowers it into the ultrasonic cleaner 133 and secures a substrate therein. The overhead conveyor then lifts the substrate 10 out of the ultrasonic tank 133, moves it over opening 869 on the dryer 134, and thence lowers the end effector 200 and substrate 10 through the opening 769 and immersed the substrate 10 in the drying liquid 866. The end effector has a pair of horizontally moveable arms 202, moveable in the direction of the arrows 208. Each arm 202 includes an edge grip surface 204 having on or more protrusions configured to contact the circumferential outer wall of the substrate 10. Each arm 202 is connected to the overhead conveyor 130 via a linkage are 208. The overhead conveyor 130 controls the horizontal spacing between the linkage arms 206, and thus between the edge grip surfaces 204 by movement thereof in the direction of arrows 210. Likewise, the overhead conveyor controls the vertical position of the linkage arms 206, and thus a substrate 10 secured in the end effector 200, by simultaneous movement thereof in the direction of arrows 212.

The Marangoni process comprises first providing the substrate 10 into the containment tank 865 through the opening 869 by the end effector 200 clamping the outer perimeter of the substrate 10. Next, the substrate 10 in a vertical orientation is dipped into the drying liquid 866a, for example, deionized water, so that the substrate 10 is fully submerged in the drying liquid 866a. The substrate 10 is then lifted from the drying liquid 866a and into the headspace 866b, as the substrate 10 is lifted out of the drying liquid 866b; IPA and Nitrogen are sprayed from the nozzles at the location of the intersection of the substrate surface with the drying liquid 866, i.e., the meniscus. When the substrate is pulled up through the stream of IPA and Nitrogen sprayed from the nozzles, the IPA displaces the drying liquid 866 on the surface of the substrate and the surface of the substrate 10 is dried.

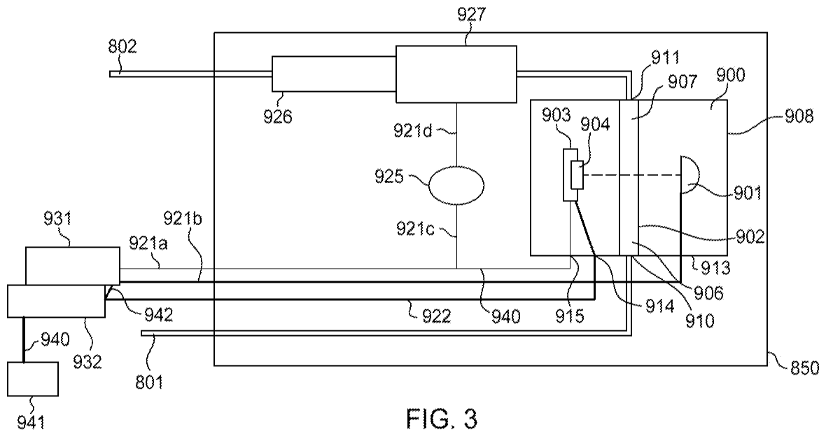

Referring now to FIG. 3, a Liquid Particle Counter (LPC) module 850 is provided herein to enable the monitoring of the condition of the drying liquid 866 in the containment tank 856 with respect to the concentration and size or type of particulates in the drying liquid 866a. The LPC module 850 includes an Ethernet line 922 connected to and from a controller having a processing function and a memory coupled to the processing function 932, a first power supply line 921a and a second power supply line 921b connected to a power supply 931, a sample inlet line 801 connected from the containment tank 865 and a sample outlet line 802 connected within the containment tank 865. The sample inlet line 801 may extend through a wall of the containment tank 865 or may be flush with the wall of the containment tank 865. A signal line 942 connects the controller and the power supply 931. The sample outlet line 802 is provided through the second opening 810b in the port 805 on the cover 804 of the containment tank 865 and extends within the containment tank 865 to a point below the upper surface of the drying liquid 866 in the containment tank 865. The sample outlet line 802 may also extend to a point above to fluid line in the containment tank 865. A pump 927 is connected to the sample inlet line 801 and when powered sucks drying liquid 866a from the containment tank 865, through a detection section of the LPC, and then pushes the liquid through a flow meter 926 and thence back to the containment tank 865 through the sample outlet line 802. As shown in FIG. 2c, the sample inlet line 801 extends through a first opening 810a in the a port 805 in the cover 804 of the tank 865, and the sample outlet line 802 extends through a second opening 810b in the port 805 on the cover 804 of the containment tank 865. The Ethernet line 903 connects to the controller 932 at the distal end thereof enters the LPC unit and connects to a photodiode 903 at the proximal end thereof. A controller line 940 connects the controller 932 to an operation manager 941 operable to control the fluid circuit of the sample inlet line 801, detection section and sample outlet line 802 based on information sent to the controller 932. The first power supply line 921a connected from the power supply 931 at the distal end thereof, enters the LPC unit and connects to the photodiode 903 at the proximal end thereof. The second power supply line 921b connected from the power supply 931 at the distal end thereof, enters the LPC unit and connects to a laser 901 at the proximal end thereof.

The first power supply line 921a connected from the power supply 931 at the distal end thereof also connects to a third power supply line 921c at a point on the first power supply line 921a between the photodiode 903 and the power supply 931. The third power supply line 921c connects from the first power supply line 921a to a speed (flow rate) control unit 925. A fourth power supply line 921d connects the speed control unit 925 to the pump 927 and the flow meter 926, thus the pump 927, flow meter 926, and the speed control unit 925 are connected to the power supply 931. The pump 927 and the flow meter 926 are connected at a portion of the sample outlet line 802 at a point between the Containment tank 865 and the LPC unit.

The LPC module 850 includes the LPC unit 900 comprising a flow tube 902, the laser 901, and a photodiode 903. The LPC unit comprises an outer unit container 908 having a first opening 910, a second opening 911 opposed to the first opening 910, a third opening 913, a fourth opening 914, and a fifth opening 915 therein. The flow tube 902 includes a first end 906 and a second end 907, and the flow tube 902 spans between and is sealingly connected through the first opening 910 to the sample inlet line 801 and through the second opening 911 to the sample outlet line 802. The first opening 910 is in fluid communication with the first end 906 of the flow tube 902 and the second end 907 of the flow tube 902 is in fluid communication with the second opening 911. The distal end of the sample end line 801 is also in fluid communication with the first opening 910, and the sample outlet line 802 is in fluid communication with the send opening 911. The pump 927 including the flow meter 926 controls the flow rate of fluid through the sample inlet line 801, the flow tube 902, and the sample outlet line 092. The flow tube 902 is composed of a transparent material that is not reactive with the liquid flowing therethrough, such as glass or a polyacrylate, thereby allowing light to enter and exit the flow tube during flow of fluid therein.

The laser 901 in the LPC unit uses a LASER diode light source and LASER beam shaping optics to illuminate a cross section of the liquid flow path within the flow tube 902. As the drying liquid 866a flows through the flow tube 902, it passes through a LASER beam emitted by the laser 901. When particles are in the flow stream of the drying liquid 866 passing through the laser beam and alighted by the laser, the signature of the intensity of the light passing through the tube and exiting the other side of the flow tube 902 changes. For example, the light can be absorbed, scattered, or partially absorbed and partially scattered by the particle. The light passing through the flow tube 902 is collected by an optical system 904 on the opposite side of the flow tube 902 to the entry location of the laser beam of the laser 901 into the flow tube 902 and imaged onto a photodiode. The photodiode converts the light into an electrical current, which is converted to voltage and amplified. The signal sent by the photodiode exits the photodiode through the Ethernet line 922, which is linked to the controller 932.

The result is a voltage pulse each time a particle crosses the LASER beam. The width of the pulse is proportional to the time it takes the particle to cross the LASER beam and the pulse's amplitude is proportional to the size of the particle. The voltage pulses created by the particles are processed by additional electronics to quantify the pulses by the size of each particle. The quantities of the various size particles are processed and stored in the sensor's buffers or transferred via the Ethernet line to the controller 932.

The controller 932 can contain software that generates a graphical display of information to a user via a user interface regarding particle size and count. The controller may also contain software that will alert a user to issues with the cleaning process based on the particle size and/or the particle count reaching a certain threshold or range of thresholds. For example, if slurry particles are detected in the vapor dryer tank 865, then a notification is sent to a service engineering team that there is an issue with cleaning in the initial clean, the brush boxes or the megasonic clean system (if applicable).

The Software in the controller can be configured to provide a number of different items of information useful to the user of the system. As discussed, it can be configured to raise an alarm when the quantity of particles detected in a predefined quantity of drying liquid 866a passing through the LPC meets or exceeds a threshold number of particles. In this scenario, the quantity of particles in a predefined quantity of fluid is indicative of the particle density in the drying liquid 866a. The system can be configured to raise an alarm when the quantity of particles of a certain size or range of sizes detected in the predefined quantity of drying fluid 866a meets or exceeds a threshold number of particles. Likewise, it can be configured to raise different alarms for different sizes or quantities of particles. For example, the LPC can be calibrated using particles of a size of the abrasive particles in the slurry, and based on a threshold number of such particles being detected in a predetermined quantity of drying liquid 866 flowing through the LPC, raise an alarm that the cleaning elements of the system prior to the drying thereof in the dryer 134 is not adequately removing the slurry from the substrates. Additionally, particles of the cleaning components such as the brushes or rollers in the brush box may have different sizes and different outlines of the shadow cast by them as they pass over the photodetector. Thus, when particles of the configuration that would be shed by a brush or roller when the brush or roller is deteriorating can be detected, and an alarm specific to the brush box needing servicing can be provided.

The operation manager 941 receives input from the controller 932 about how to process drying liquid 866a through the LPC module 850 circuit. The controller may for example, signal to the system to begin pumping the drying liquid 866a through the LPC module by user input or system input signaling that the start of sampling of the drying liquid 866a is needed. A signal is sent to the controller 932 through the signal line 942, and the controller turns on the power supply 932. Power is supplied to the speed control, the pump 927 and flow meter 926, as well as the photodiode 903 in the LPC unit 900. The pump 927 pulls drying liquid 866a from the Containment tank 865, through the LPC unit 900, and outputs the drying liquid 866a back into the Containment tank 865. The controller will send a signal to the speed control 925 to cause the fluid to be pumped more or less quickly, i.e., to modify the flow rate of the drying liquid 866a through the LPC, or to start and stop flow of the drying liquid 866a through the LPC to create in pulses of drying liquid 866a through the LPC unit 900. The controller sends a signal to the controller 932 either to engage in particle detection in the drying liquid 866a continuously as substrate processing proceeds or to engage in particle detection in the drying liquid 866a in the Containment tank 865 intermittently. The particle detection in the drying liquid 866a may be performed intermittently by receiving a signal from the controller that a substrate is currently being processed, and only perform particle detection in the drying liquid 866a before, during, or after a substrate is being processed or a combination thereof. The particle detection in the drying liquid 866a may be performed intermittently by receiving a signal from the controller to perform particle detection in the drying liquid 866a in time spaced pulses regardless of whether a substrate is being processed. Likewise, particle detection in the drying liquid 866a may be performed continuously.

The controller 932 receives information from the photodiode about the size of the particles processed in the LPC module 900. The controller 932 receives information from the photodiode about the shape of the particles processed in the LPC module 900. The controller 932 uses software to determine if the number of the particles being processed through the LPC module per unit of time reach an alarm threshold. An alarm will be triggered if the particles per unit of time reach a certain threshold. The alarm can be visual, audio, or an electronic message. The information provided to the controller about the size and shape of the particles detected can be analyzed by the software and provide a user with information about possible issues. For example, larger particles may indicate a break down in the brush box, or smaller particles may indicate issues with a slurry formula or cleaning.

A number of embodiments of the invention have been described. Nevertheless, it will be understood that various modifications may be made without departing from the spirit and scope of the invention. Accordingly, other embodiments are within the scope of the following claims.

What is claimed is:

1. An apparatus for drying substrates, comprising:
a containment tank having a rinsing liquid region and a headspace; and
a particle detector comprising:
an inlet line;
a liquid particle counter configured to receive a flow of liquid from the containment tank via the inlet line and to output information about particles in the liquid;
an outlet line; and
a pump configured to cause the liquid to be drawn from the containment tank into the liquid particle counter through the inlet line and returned to the containment tank through the outlet line.

2. The apparatus of claim 1, further comprising a controller operable to control the flow of liquid through the particle detector.

3. The apparatus of claim 1, further comprising a speed control unit operable to control a rate of the flow of liquid.

4. The apparatus of claim 1, wherein the outlet line has a fluid outlet connected to the rinsing liquid region of the containment tank.

5. The apparatus of claim 1, further comprising a controller configured to discriminate particles based on size from the information provided from the liquid particle counter.

6. The apparatus of claim 1, further comprising a controller configured to output an alarm based on the information obtained from the liquid particle counter.

7. The apparatus of claim 1, further comprising a controller configured to discriminate particles based on shape from the information provided from the liquid particle counter.

8. A polishing, cleaning and drying apparatus, comprising:
a polishing module to polish a substrate;
a physical contact module to clean the substrate after the polishing;
a vapor dryer to dry the substrate after the substrate is cleaned by submerging the substrate in rinsing liquid of a rinsing liquid region and drying the substrate as the substrate is removed from the rinsing liquid; and
a liquid particle counter to receive a flow of the rinsing liquid from the vapor dryer and to output information about particles in the rinsing liquid.

9. The apparatus of claim 8, further comprising a controller configured to control the flow of the rinsing fluid through the liquid particle counter.

10. The apparatus of claim 8, further comprising a speed control unit configured to control a rate of the flow of the rinsing fluid through the liquid particle counter.

11. The apparatus of claim 8, further comprising an outlet line having a fluid outlet that is disposed in the rinsing liquid region.

12. The apparatus of claim 8, further comprising a controller configured to discriminate particles based on size from the information provided from the liquid particle counter.

13. The apparatus of claim 8, further comprising a controller configured to output an alarm based on the information obtained from the liquid particle counter.

14. The apparatus of claim 8, further comprising a controller configured to discriminate particles based on shape the information provided from the liquid particle counter.

15. A method of substrate processing, the method comprising:
polishing a substrate;
after the polishing, cleaning the substrate; and
after cleaning the substrate, submerging the substrate into a rinsing liquid and drying the substrate as the substrate is removed from the rinsing liquid; and
passing the rinsing liquid through a liquid particle counter.

16. The method of claim 15, further comprising returning the rinsing liquid to a rinsing liquid region through an outlet line.

17. The method of claim 15, further comprising continuously passing the rinsing liquid through an inlet line and through the liquid particle counter.

18. The method of claim 15, further comprising intermittently passing the rinsing liquid through an inlet line and through the liquid particle counter.

19. The method of claim 15, further comprising setting off an alarm based on information obtained from the liquid particle counter.

20. The method of claim 19, wherein the alarm is one of a visual, audio, or an electronic message alarm.
